(19) United States
(12) Patent Application Publication
(10) Pub. No.: US 2026/0313958 A1
(43) Pub. Date: Oct. 8, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventor: Po-Yu Yang, Hsinchu City (TW)

(73) Assignee: UNITED MICROELECTRONICS CORP., Hsin-Chu City (TW)

(21) Appl. No.: 19/198,130

(22) Filed: May 5, 2025

(30) Foreign Application Priority Data
Apr. 7, 2025 (TW) 114112945

(51) Int. Cl. H10D 30/66; H10D 30/01; H10D 62/832; H10D 64/00; H10D 64/01

(52) U.S. Cl. CPC H10D 30/668; H10D 30/0297; H10D 62/8325; H10D 64/01; H10D 64/117

(57) ABSTRACT

A method for fabricating a semiconductor device includes the steps of forming a first trench in a substrate, forming a gate dielectric layer in the first trench, forming a gate structure on the gate dielectric layer, removing part of the gate structure and part of the substrate to form a second trench, forming a liner in the second trench, forming a field plate in the second trench, forming a passivation layer on the gate structure, forming a source electrode on the substrate to connect to the field plate, and forming a drain electrode on a backside of the substrate.

### BACKGROUND OF THE INVENTION

### 1. Field of the Invention

The invention relates to a semiconductor device and fabrication method thereof, and more particularly to a silicon carbide (SiC) metal oxide semiconductor field effect transistor (MOSFET) and method for fabricating the same.

### 2. Description of the Prior Art

Typical power semiconductor device includes insulated gate bipolar transistors (IGBTs) and metal oxide semiconductor field effect transistor (MOSFET) device, within which silicon carbide (SiC) MOSFET has critical breakdown strength, can operate at much higher temperatures, provide higher current density, and support higher switching frequencies.

Although semiconductor device such as SiC MOSFET has the above-mentioned advantages, the gate oxide of silicon carbide (SiC) MOSFET is especially vulnerable on voltage spiking induced on gate bias during operation and electrostatic discharge (ESD) stress because of thinner gate oxide thickness and lower oxide quality. In conventional approach, additional devices may be added for protecting gate oxide from voltage overshot and ESD stress. However, extra space is usually required for accommodating these devices, which ultimately increases cell pitch of the entire device. Since conventional approach for fabricating SiC MOSFETs still exist numerous problems, how to come up with a novel approach for fabricating SiC MOSFETs to resolve the above issues has become an important task in this field.

### SUMMARY OF THE INVENTION

According to an embodiment of the present invention, a method for fabricating a semiconductor device includes the steps of forming a first trench in a substrate, forming a gate dielectric layer in the first trench, forming a gate structure on the gate dielectric layer, removing part of the gate structure and part of the substrate to form a second trench, forming a liner in the second trench, forming a field plate in the second trench, forming a passivation layer on the gate structure, forming a source electrode on the substrate to connect to the field plate, and forming a drain electrode on a backside of the substrate.

According to another aspect of the present invention, a semiconductor device includes a field plate in a substrate, a first gate structure adjacent to one side of the field plate, a second gate structure adjacent to another side of the field plate, a source electrode on the substrate and connected to the field plate, and a drain electrode on a backside of the substrate.

According to yet another aspect of the present invention, a semiconductor device includes a field plate in a substrate, a first gate structure adjacent to one side of the field plate, a second gate structure adjacent to another side of the field plate, a first gate dielectric layer adjacent to the first gate structure, a liner between the field plate and the first gate structure, a source electrode on the substrate and connected to the field plate, and a drain electrode on a backside of the substrate. Preferably, the liner and the first gate dielectric layer have different thickness.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating a semiconductor device according to an embodiment of the present invention.

FIG. 8 illustrates a structural view of a semiconductor device according to an embodiment of the present invention.

FIG. 9 illustrates a structural view of a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

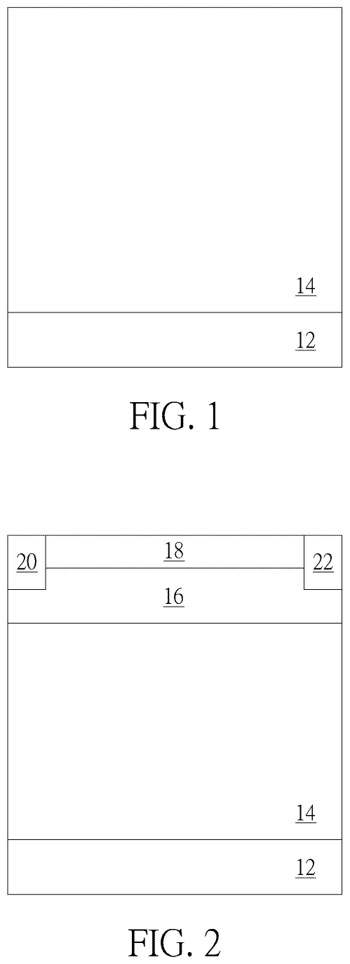

Referring to FIGS. 1-7, FIGS. 1-7 illustrate a method for fabricating a semiconductor device according to an embodiment of the present invention. As shown in FIG. 1, a substrate 12 made of semiconductor material is provided, in which the substrate 12 preferably includes a silicon carbide (SiC) substrate or more specifically a N+ SiC substrate. Nevertheless, according to other embodiment of the present invention, the substrate 12 could also include a silicon substrate, an epitaxial silicon substrate, or even a silicon-on-insulator (SOI) substrate, which are all within the scope of the present invention. Next, an epitaxial growth process could be conducted to form a drift region 14 on the substrate 12, in which the drift region 14 could include a N− drift region, but not limited therein.

Next, as shown in FIG. 2, from bottom to top a body region 16 and a doped region 18 are formed on the drift region 14 and doped regions 20, 22 are formed adjacent to two sides of the gate structure (not shown) or gate dielectric layer (not shown) yet to be formed afterwards. In this embodiment, the drift region 14 preferably includes a N− drift region, the body region 16 includes a P+ doped region, the doped region 18 includes a N+ doped region, and each of the doped regions 20, 22 includes a P+ doped region. Moreover, the depth of the doped regions 20, 22 is greater than the depth of the doped region 18 or that the bottom surface of the doped regions 20, 22 is slightly lower than the bottom surface of the doped region 18.

Next, as shown in FIG. 3, a photo-etching process is conducted to form a first trench 24 in the substrate 12. In this embodiment, the formation of the first trench 24 could be accomplished by first using a patterned mask such as patterned resist as mask to remove part of the substrate 12 including part of the doped region 18, part of the body region 16, and even part of the drift region 14 through an etching process for forming a first trench 24. Preferably, the bottom surface of the first trench 24 could be slightly lower than the bottom surface of the body region 16 as shown in this embodiment, or could also be even with or slightly higher than the bottom surface of the body region 16 but still lower than the top surface of the body region 16, which are all within the scope of the present invention.

It should be noted that after removing part of the doped region 18 to form the first trench 24, the remaining doped region 18 is then divided into doped regions 26 and 28 adjacent to two sides of the first trench 24, in which the width of each of the doped regions 26, 28 could be substantially equal to the width of each of the adjacent doped regions 20, 22. For clarity purpose, the drift region 14, body region 16, and doped regions 20, 22, 26, 28 above the substrate 12 will all be referred to as the substrate 12 in the following embodiments as the first trench 24 is formed in the substrate 12.

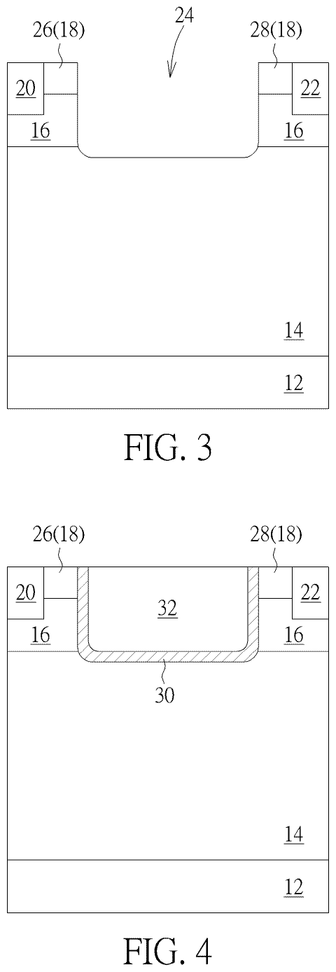

Next, as shown in FIG. 4, a gate dielectric layer 30 and a gate material layer (not shown) are formed in the first trench 24 and surface of the substrate 12 adjacent to two sides of the first trench 24 while filling the first trench 24 completely. Next, as planarizing process such as a chemical mechanical polishing (CMP) process is conducted to remove part of the gate material layer and part of the gate dielectric layer 30 so that the top surface of the remaining gate dielectric layer 30 and gate material layer is even with the top surface of the substrate 12 on two adjacent sides. This forms a gate structure 32 in the first trench 24 and a patterned gate dielectric layer 30 between the substrate 12 and the gate structure 32. In this embodiment, the gate dielectric layer 30 could include silicon oxide and the gate material layer or gate structure 32 could include polysilicon or metal, but not limited thereto.

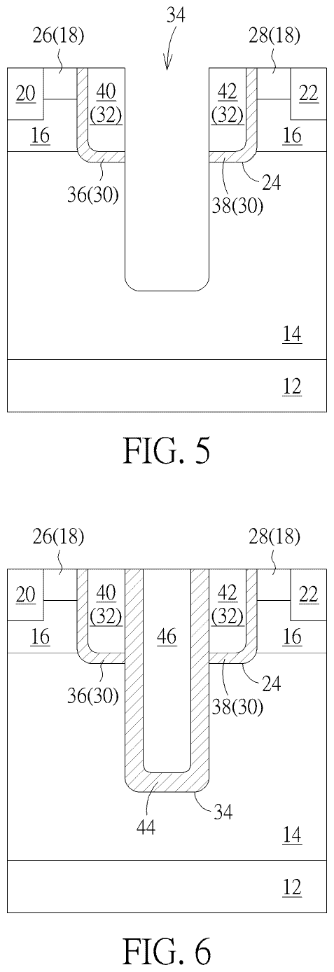

Next, as shown in FIG. 5, another photo-etching process is conducted to form a second trench 34 in the substrate 12. In this embodiment, the formation of the second trench 34 could be accomplished by using a patterned mask such as patterned resist as mask to remove part of the gate structure 32, part of the gate dielectric layer 30, and part of the substrate 12 directly under the gate structure 32 through an etching process for forming the second trench 34. Preferably, the bottom surface of the second trench 34 is slightly lower than the bottom surface of the first trench 24 and the depth of the second trench 34 such as the distance measuring from the bottom surface to the top surface of the second trench 34 could be greater than once, twice, three times, or even more than three times the depth of the first trench 24, which are all within the scope of the present invention.

It should be noted that after part of the gate structure 32 and part of the gate dielectric layer 30 are removed to form the second trench 34, the remaining gate dielectric layer 30 and gate structure 32 are divided into gate dielectric layers 36, 38 and gate structures 40, 42 adjacent to two sides of the second trench 34, in which bottom surfaces of the gate dielectric layers 36, 38 are coplanar, bottom surfaces of the gate structures 40, 42 are coplanar, and the width of each of the gate structures 40, 42 could be slightly greater than the width of each of the doped regions 20, 22, 26, 28 but less than the width of the second trench 34. The gate dielectric layer 30 that originally has a U-shape cross-section at this stage is transformed into gate dielectric layers 36, 38 each having a L-shape cross-section between the substrate 12 and the gate structures 40, 42.

Next, as shown in FIG. 6, a liner 44 and a field plate 46 are formed into the second trench 34 and on the surface of the substrate 12 adjacent to two sides of second trench 34 to fill the second trench 34 completely, and then a planarizing process such as CMP is conducted to remove part of the field plate 46 and part of the liner 44 so that the top surface of the remaining field plate 46 and liner 44 is even with the top surface of the substrate 12. In this embodiment, the liner 44 preferably includes silicon oxide while the field plate 46 and the aforementioned gate structure 32 could be made of same or different material. For instance, the field plate 46 could include polysilicon or metal, but not limited thereto. Moreover, even though the thickness of the liner 44 is slightly greater than the thickness of each of the gate dielectric layers 36, 38, according to other embodiment of the present invention, the liner 44 and each of the gate dielectric layers 36, 38 could also share same thickness, which is also within the scope of the present invention.

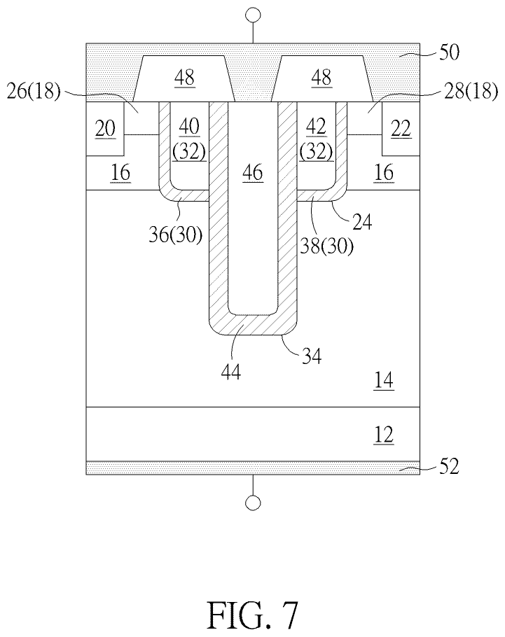

Next, as shown in FIG. 7, a passivation layer 48 is formed on the gate structures 40, 42, and then a source electrode 50 is formed to connect to the field plate 46. Specifically, a passivation layer 48 made of silicon oxide could be formed on the substrate 12 to cover the field plate 46, the gate structures 40, 42, and the doped regions 20, 22, 26, 28 entirely, and then a photo-etching process is conducted by using patterned mask as mask to remove part of the passivation layer 48 through etching so that the remaining or patterned passivation layer 48 is disposed on the liner 44, the gate structures 40, 42, the gate dielectric layers 36, 38, and the doped regions 26, 28 while not covering the doped regions 20, 22 and major part or even all of the field plate 46. Preferably, the patterned passivation layer 48 could have two slanted sidewalls as shown in FIG. 7 or could have two vertical sidewalls perpendicular to the surface of the substrate 12, which are all within the scope of the present invention.

Next, a source electrode 50 is formed to cover the passivation layer 48 and the doped regions 20, 22 and connect to the field plate 46. In this embodiment, the source electrode 50 could include conductive material or metal material such as aluminum (Al), titanium (Ti), or titanium nitride (TiN). Next, the substrate 12 could be reversed and a deposition process is conducted to form a conductive layer on the backside or bottom surface of the substrate 12 serving as a drain electrode 52. In this embodiment, the drain electrode 52 and the source electrode 50 could include same material or different material. For instance, the drain electrode 52 could include conductive material or metal such as Al, Ti, or TiN. This completes the fabrication of a semiconductor device or SiC MOSFET.

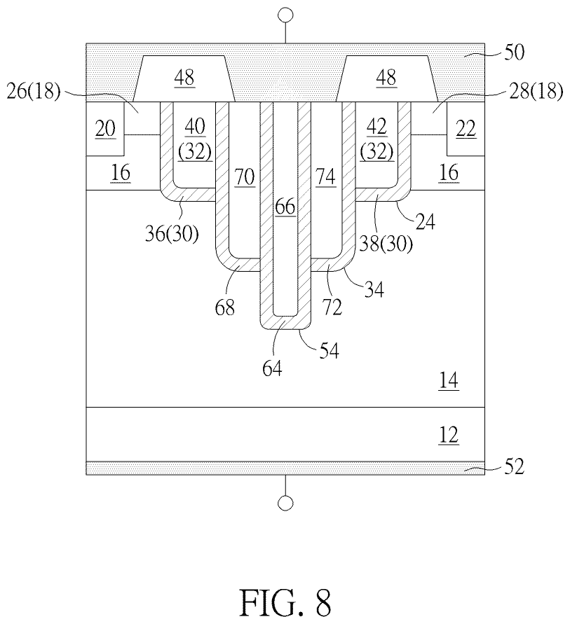

Referring to FIG. 8, FIG. 8 illustrates a structural view of a semiconductor device according to an embodiment of the present invention. As shown in FIG. 8, in contrast to the embodiment in FIG. 7 of only forming a single field plate 46 in the substrate 12 between gate structures 40, 42, it would also be desirable to adjust the size of the second trench 34 during formation of the second trench 34 in FIG. 5 by enlarging the overall width of the second trench 34 but slightly reducing the depth of the second trench 34, and then follow the fabrication process conducted in FIG. 6 by depositing a liner 44 and field plate 46 in the second trench 34 accompanied by a planarizing process. Next, another photo-etching process is conducted to remove part of the field plate 46, part of the liner 44, and part of the substrate 12 directly under the liner 44 to form a third trench 54, another liner 64 and another field plate 66 are formed in the trench 54, and a planarizing process is conducted to remove part of the liner 64 and part of the field plate 66 so that the top surface of the remaining liner 64 and field plate 66 is even the top surface of the substrate 12.

It should be noted that the photo-etching process conducted to remove part of the liner 44 and part of the field plate 46 at this stage preferably divides the liner 44 and field plate 46 into two parts including liner 68 and field plate 70 on left side of the filed plate 66 and liner 72 and field plate 74 on right side of the field plate 66. Preferably, the bottom surface of the middle field plate 66 is lower than the bottom surfaces of the field plates 70, 74 on two adjacent sides, the three field plates 66, 70, 74 could have same or different width, and the width of each of the field plates 66, 70, 74 could be slightly less than the width of each of the gate structures 40, 42. In this embodiment, the multiple field plate design could be used to provide novel electric field peak and lower maximum electrical field near edge portion of the gate structure.

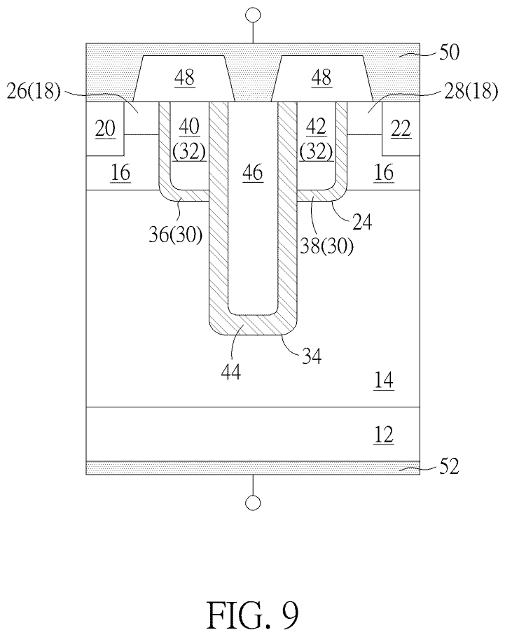

Referring to FIG. 9, FIG. 9 illustrates a structural view of a semiconductor device according to an embodiment of the present invention. As shown in FIG. 9, in contrast to the gate dielectric layers 36, 38 and liner 44 in the embodiment in FIG. 8 are all made of silicon oxide, according to other embodiment of the present invention, the gate dielectric layers 36, 38 and/or the liner 44 could also be made of a high-k dielectric layer with higher dielectric constant. In other words, the gate dielectric layers 36, 38 and the liner 44 in this embodiment could be made of same or different material composition while having different material combination. For instance, the gate dielectric layers 36, 38 could be made of silicon oxide while the liner 44 could be made of high-k dielectric layer, the gate dielectric layers 36, 38 could be made of high-k dielectric layer while the liner 44 is made of silicon oxide, or all the gate dielectric layers 36, 38 and the liner 44 are made of same or different high-k dielectric layer, which are all within the scope of the present invention.

In this embodiment, the high-k dielectric layer is preferably selected from dielectric materials having dielectric constant (k value) larger than 4. For instance, the high-k dielectric layer may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof. Preferably, the BBM layer could be selected from the group consisting of TiN and TaN, but not limited thereto.

Moreover, the gate dielectric layers 36, 38 and the liner 44 could also have different thickness, in which the thickness of the liner 44 is preferably slightly greater than the thickness of each of the gate dielectric layers 36, 38. For instance, the thickness of the liner 44 could be greater than once, twice, three times, or even more than three times the width of each of the gate dielectric layers 36, 38, which are all within the scope of the present invention. By choosing high-k dielectric material to form the gate dielectric layers and/or liner, the present invention is able to improve turn-on resistance (R_{ON}) of the device and by keeping the thickness of the liner 44 to be greater than the thickness of the gate dielectric layers, breakdown voltage (V_{BD}) of the device could also be improved significantly.

Overall, the present invention discloses a SiC MOSFET and fabrication method thereof, which first forms a first trench 24 in a substrate, forms a gate structure in the first trench, removes part of the gate structure and part of the substrate to form a second trench and at the same time divides the gate structure into two portions, and then deposits a liner and a field plate into the second trench. According to the embodiment shown in FIG. 7, by forming buried type gate structures adjacent to two sides of the buried type filed plate, it would be desirable to lower peak electric field near edge region of the gate structure substantially.

In addition to only disposing a single field plate in the substrate, according to the embodiment shown in FIG. 8, it would also be desirable to form a third trench after the formation of field plate in FIG. 6 is completed by dividing the field plate into two portions, and then deposit another field plate into the third trench for forming a triple field plate structure. According to yet another embodiment shown in FIG. 9, it would additionally be desirable to use higher dielectric constant material such as a high-k dielectric layer for forming the gate dielectric layers 36, 38 adjacent to the gate structure and/or the liner 44 adjacent to the field plate while the gate dielectric layers 36, 38 and the liner 44 could also have same or different thickness depending on the demand of the product, which are all within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a first trench in a substrate;
forming a gate structure in the first trench;
removing the gate structure and the substrate to form a second trench; and
forming a field plate in the second trench.

2. The method of claim 1, further comprising:
forming a body region on the substrate;
forming a first doped region on the body region;
forming second doped regions adjacent to two sides of the first trench;
forming the first trench;
forming a gate dielectric layer in the first trench;
forming the gate structure on the gate dielectric layer;
forming the second trench;
forming a liner in the second trench;
forming the field plate on the liner;
forming a passivation layer on the gate structure;
forming a source electrode on the substrate to connect to the field plate; and
forming a drain electrode on a backside of the substrate.

3. The method of claim 2, wherein the body region and the second doped regions comprise same conductive type.

4. The method of claim 2, wherein the body region and the first doped region comprise different conductive type.

5. The method of claim 2, wherein the first doped region and the second doped regions comprise different conductive type.

6. The method of claim 2, wherein a depth of the second doped regions is greater than a depth of the first doped region.

7. The method of claim 2, wherein a depth of the first trench is greater than a depth of the body region.

8. A semiconductor device, comprising:
a field plate in a substrate;
a first gate structure adjacent to one side of the field plate;
a second gate structure adjacent to another side of the field plate;
a source electrode on the substrate and connected to the field plate; and
a drain electrode on a backside of the substrate.

9. The semiconductor device of claim 8, further comprising:
a body region adjacent to two sides of the first gate structure and the second gate structure;
a first doped region and a second doped region adjacent to one side of the first gate structure;
a third doped region and a fourth doped region adjacent to one side of the second gate structure; and
a passivation layer on the first gate structure and the second gate structure.

10. The semiconductor device of claim 9, wherein the first doped region and the second doped region comprise different conductive type.

11. The semiconductor device of claim 9, wherein the third doped region and the fourth doped region comprise different conductive type.

12. The semiconductor device of claim 9, further comprising:
a first gate dielectric layer between the first gate structure and the body region;
a second gate dielectric layer between the second gate structure and the body region; and
a liner between the field plate and the first gate structure.

13. The semiconductor device of claim 12, wherein the liner comprises a U-shape.

14. The semiconductor device of claim 12, wherein the first gate dielectric layer comprises a L-shape.

15. A semiconductor device, comprising:
a field plate in a substrate;
a first gate structure adjacent to one side of the field plate;
a second gate structure adjacent to another side of the field plate;
a first gate dielectric layer adjacent to the first gate structure;
a liner between the field plate and the first gate structure, wherein the liner and the first gate dielectric layer comprise different thickness;
a source electrode on the substrate and connected to the field plate; and
a drain electrode on a backside of the substrate.

16. The semiconductor device of claim 15, further comprising:
a body region adjacent to two sides of the first gate structure and the second gate structure;
a first doped region and a second doped region adjacent to one side of the first gate structure;
a third doped region and a fourth doped region adjacent to one side of the second gate structure; and
a passivation layer on the first gate structure and the second gate structure.

17. The semiconductor device of claim 15, further comprising a second gate dielectric layer adjacent to the second gate structure, wherein first gate dielectric layer and the second gate dielectric comprise same material.

18. The semiconductor device of claim 15, wherein a dielectric constant of the first gate dielectric layer is greater than a dielectric constant of the liner.

19. The semiconductor device of claim 15, wherein the first gate dielectric layer comprises a high-k dielectric layer.

20. The semiconductor device of claim 15, wherein a thickness of the first gate dielectric layer is less than a thickness of the liner.
